(19) United States
(12) Patent Application Publication
(10) Pub. No.: US 2011/0294452 A1
(43) Pub. Date: Dec. 1, 2011

(54) ANTENNA AMPLIFIER DEVICE AND ANTENNA DEVICE PROVIDED IN MOBILE OBJECT

(75) Inventors: Kenji KAWAI, Kobe-shi (JP); Kazuo TAKAYAMA, Kobe-shi (JP)

(73) Assignee: FUJITSU TEN LIMITED, Kobe-shi (JP)

(21) Appl. No.: 13/107,313

(22) Filed: May 13, 2011

(30) Foreign Application Priority Data
May 26, 2010 (JP) 2010-120678

(51) Int. Cl. H04B 1/18; H03F 1/56

(52) U.S. Cl. 455/293; 330/185

(57) ABSTRACT

Even when an input is weak, an antenna amplifier device may achieve a high sensitivity while reducing a noise factor (NF). The antenna amplifier device includes an amplification circuit 7 for amplifying a high frequency signal received by an antenna A, and an NF matching circuit 5 provided between the amplification circuit 7 and the antenna A of which input impedance has a capacitance, the NF matching circuit 5 for switching the input impedance to the amplification circuit 7 in accordance with a reception frequency. The NF matching circuit 5 includes a plurality of coils having different inductances, and at least one switch SW for connecting one of the coils, selected in accordance with the reception frequency, between the antenna A and the amplification circuit 7. A step-up coil SC is interposed between the NF matching circuit 5 and the amplification circuit 7.

This application is based on an application No. 2010-120678 filed in Japan, the contents of which are hereby incorporated by reference.

### BACKGROUND OF THE INVENTION

1. Field of the Invention

The present invention relates to an antenna amplifier device and an antenna device.

2. Description of the Related Art

In a reception system provided in a mobile object for receiving broadcast waves such as AM broadcasting, FM broadcasting, and digital television broadcasting, an antenna amplifier device is used to reduce transmission loss by matching impedances between an antenna and an audio apparatus and to prevent reduction of an S/N ratio.

Japanese Unexamined Patent Publication No. H10-209897 discloses a tunable antenna device having an antenna element of ¼ wavelength with respect to a reception frequency and always obtaining an optimum VSWR according to the reception frequency of a receiver. The tunable antenna device has an LC series resonance circuit interposed between a base portion of a reception antenna and an antenna input terminal of the receiver.

The LC series resonance circuit has an electronic variable capacitance element and an inductive element. The electronic variable capacitance element attains a capacitance value according to a direct current control voltage when the direct current control voltage corresponding to a reception frequency is applied. The inductive element is connected in series with the electronic variable capacitance element. The inductive element attains an inductive reactance +jXL equivalent to a capacitive reactance −jXc of the electronic variable capacitance element when the electronic variable capacitance element attains a capacitance value in a central portion of a tunable capacitance range corresponding to a central portion of a band of the reception frequency.

Japanese Unexamined Patent Publication No. H06-216795 discloses a vehicle antenna device having an impedance matching circuit between an antenna and a receiver to provide a high gain in a relatively wide frequency range. In the vehicle antenna device, a reception frequency band is divided into two portions, i.e., an upper side and a lower side. The vehicle antenna device includes an upper side impedance matching circuit, a lower side impedance matching circuit, and a selector for selecting one of the impedance matching circuits in accordance with the reception frequency.

Although a high gain can be obtained with use of any of the above conventional impedance matching circuits, an amplification circuit does not necessarily provide a good noise factor (NF).

In general, it is theoretically confirmed that a noise factor (NF) of an amplifier is determined based on a signal source impedance, an input impedance of the amplifier, and an equivalent noise resistance unique to an amplification element constituting the amplifier. Since the input impedance and the equivalent noise resistance are determined based on a transistor used and a grounding method, the noise factor (NF) is ultimately determined based on the signal source impedance.

In general, an amplification circuit incorporated into an antenna amplifier device uses an FET having a high input impedance. A step-up coil is connected between the antenna and the amplification circuit in order to input a high frequency signal received by the antenna into the FET with a low loss. The step-up coil is a transformer having a larger turn ratio of a secondary coil with respect to a primary coil so that the secondary impedance is further increased.

Although a signal level can be improved by increasing the signal source impedance with use of the step-up coil or the like, a noise voltage also increases due to the equivalent noise resistance of the FET itself. Therefore, there is a problem that a noise level also increases.

In particular, when a weak input signal received by an antenna is amplified by an amplification circuit in a mobile object traveling in a low magnetic field area, the noise factor (NF) is significantly deteriorated.

### SUMMARY OF THE INVENTION

In view of the conventional problems described above, it is an object of the present invention to provide an antenna amplifier device and an antenna device providing a high sensitivity while reducing a noise factor (NF) even when an input is weak.

In order to achieve the object, an antenna amplifier device according to the present invention includes an amplification circuit for amplifying a high frequency signal received by an antenna, and an NF matching circuit provided between the amplification circuit and the antenna of which input impedance is capacitive. The NF matching circuit switches the input impedance to the amplification circuit in accordance with a reception frequency.

According to the above configuration, the input impedance to the amplification circuit is switched in accordance with the reception frequency by the NF matching circuit. Therefore, even when an input is weak, the high frequency signal received by the antenna is amplified by the amplification circuit with a high sensitivity and a low noise factor (NF).

A step-up coil is preferably interposed between the NF matching circuit and the amplification circuit. In this case, the signal is amplified with a high sensitivity and a low noise factor (NF).

When an antenna having an extremely short antenna length is used to receive a broadcast wave having a long wavelength, the antenna impedance is capacitive. Therefore, the NF matching circuit preferably includes a plurality of coils having different inductances and a switch for connecting one of the coils, selected in accordance with the reception frequency, between the antenna and the amplification circuit.

An antenna according to the present invention includes the above antenna amplifier devices, the antenna amplifier devices arranged near to the plurality of antennas, for amplifying high frequency signals received by the antennas, a demodulation unit for demodulating the high frequency signal output from each of the antenna amplifier devices, a multiplexing processing unit for multiplexing each demodulated signal demodulated by the demodulation unit, a data transmission device for transmitting the demodulated signal multiplexed by the multiplexing processing unit to a head unit via a data transmission line, and a high frequency control unit for controlling the NF matching circuit on the basis of channel select information transmitted from the head unit via the data transmission device.

The high frequency control unit for controlling the NF matching circuit provided in the antenna amplifier device can perform integral control on the basis of the channel select information for each of the antenna amplifier devices transmitted from the head unit via the data transmission line. Therefore, the antenna device can achieve high performance while reducing cost due to the reduction of the number of components and the reduction of implementation spaces, as compared with a case where separate control signal lines are provided to transmit the channel select information from the head unit to the respective antenna amplifier devices and separate high frequency control units are provided to control the respective antenna amplifier devices.

### BRIEF DESCRIPTION OF THE DRAWINGS

FIG. 1A is an explanatory diagram illustrating circuit blocks in an antenna amplifier device;

FIG. 1B is a schematic diagram illustrating an NF matching circuit;

FIG. 1C is a schematic diagram illustrating an antenna amplifier device in which a step-up coil is connected to the NF matching circuit;

FIG. 2A is an input equivalent circuit diagram of an FET constituting an amplification circuit;

FIG. 2B is a diagram illustrating characteristics of the NF matching circuit;

FIG. 3A is a schematic diagram of another example of an NF matching circuit;

FIG. 3B is a schematic diagram of still another example of an NF matching circuit;

FIG. 4A is an explanatory diagram illustrating operation of an attenuator when an weak input is provided to the antenna amplifier device;

FIG. 4B is an explanatory diagram illustrating operation of the attenuator when a strong input is provided to the antenna amplifier device;

FIG. 5A is a circuit diagram illustrating the attenuator, for explaining operation with a weak input;

FIG. 5B is a circuit diagram illustrating the attenuator, for explaining operation with a strong input;

FIG. 6A is a circuit diagram illustrating a tuning circuit;

FIG. 6B is a circuit diagram illustrating a switching circuit;

FIG. 7A is a partially cutaway perspective view illustrating an arrangement of an antenna-side device and a head unit;

FIG. 7B is a plan view illustrating the arrangement of the antenna-side device and the head unit;

FIG. 8 is an explanatory diagram illustrating circuit blocks of the head unit and the antenna device into which the antenna amplifier device is incorporated; and

FIG. 9 is an explanatory diagram illustrating a transmission frame generated by a multiplexing processing unit.

### DESCRIPTION OF THE EMBODIMENTS

An antenna amplifier device according to the present invention and an antenna device into which the antenna amplifier device is incorporated will be hereinafter explained.

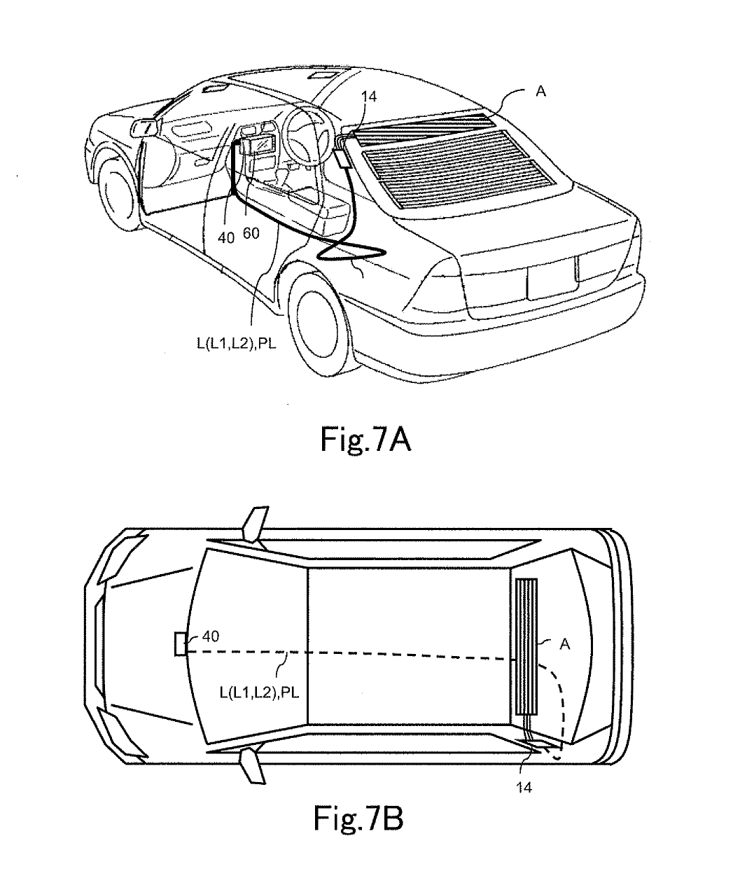

As shown in FIGS. 7A, 7B, a plurality of antennas A for receiving broadcast waves of different signal systems, such as an AM broadcasting reception antenna, an FM broadcasting reception antenna, and a digital TV reception antenna, are provided on a rear window of an automobile serving as a mobile object. An antenna device 14 is provided near to the respective antennas. In FIGS. 7A, 7B, the antennas A for three systems are shown simply such that they are provided in one region. However, the antennas A for the three systems may be provided in different regions.

A controller 60 of an audio apparatus is provided in front of the left of a driver's seat. A head unit 40 serving as an integrated reception apparatus is provided near to the controller 60. The antenna device 14 and the head unit 40 are connected with two data transmission lines L (L1, L2) and a feeder cable PL.

One of the data transmission lines L is the data transmission line L1 for transmitting broadcast wave data from the antenna device 14 to the head unit 40. The other one of the data transmission lines L is the transmission line L2 for transmitting control data from the head unit 40 to the antenna device 14. Electric power is supplied from the head unit 40 to the antenna device 14 via the power line PL.

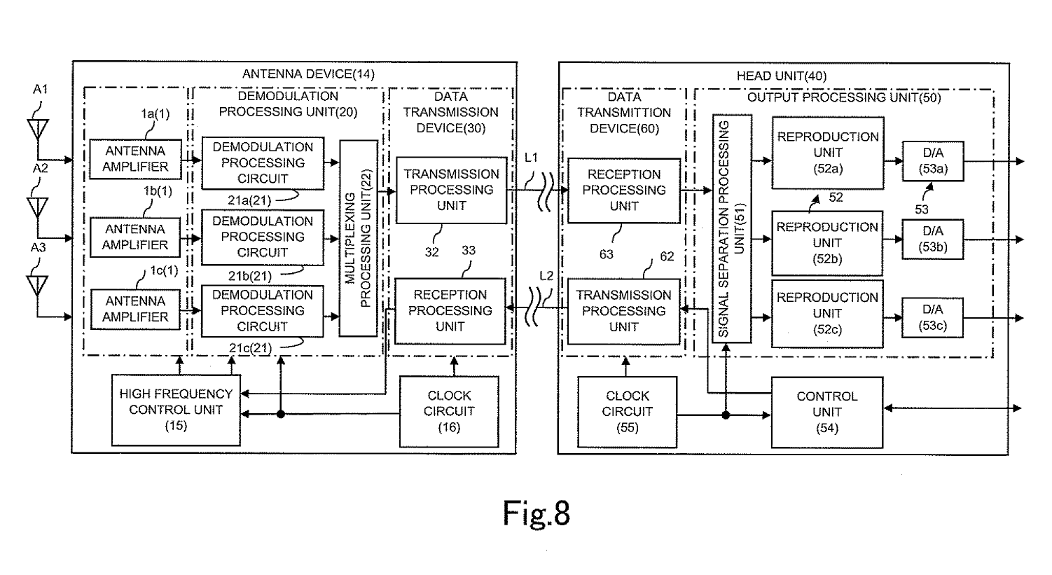

As shown in FIG. 8, the antenna device 14 includes antenna amplifier devices 1 (1a, 1b, 1c) according to the present invention, a demodulation processing unit 20, a data transmission device 30, a high frequency control unit 15, and the like. The data transmission device 30 includes a transmission processing unit 32 and a reception processing unit 33.

Further, the antenna device 14 has a clock circuit 16 including a clock signal source and a frequency divider for generating a clock signal of a required frequency. The demodulation processing unit 20, the high frequency control unit 15, the data transmission device 30, and the like operate on the basis of the clock signal generated by the clock circuit 16.

The antenna amplifier devices 1 (1a, 1b, 1c) are respectively connected to a plurality of antennas A1, A2, A3 of different signal systems via coaxial cables. The antenna amplifier devices 1 are configured to amplify high frequency signals received by the antennas. For example, the antenna A1 receives AM broadcasting waves, the antenna A2 receives FM broadcasting waves, and the antenna A3 receives digital television broadcasting waves.

The demodulation processing unit 20 includes demodulation circuits 21 (21a, 21b, 21c) and a multiplexing processing unit 22. The demodulation circuits 21 (21a, 21b, 21c) function as demodulation units for respectively demodulating the high frequency signals processed by the antenna amplifier devices 1 (1a, 1b, 1c). The multiplexing processing unit 22 generates frame data obtained by multiplexing the demodulated signals demodulated by the demodulation circuits 21 (21a, 21b, 21c) into one signal system.

Each of the demodulation circuits 21 includes a frequency converter for down-converting the high frequency signal output from the antenna amplifier device 1 into an intermediate frequency, a band-pass filter for removing low and high frequency components from the down-converted signal, an A/D converter for A/D converting the filtered signal, an orthogonal transformation device or a low-pass filter, and the like.

Each of the broadcast wave data of AM broadcasting and the broadcast wave data of FM broadcasting, A/D converted by the A/D converter, is transformed into orthogonal data having an I component and a Q component by the orthogonal transformation device, and the orthogonal data is then input to the multiplexing processing unit 22. The broadcast wave data of a digital TV are filtered by the low-pass filter, and is thereafter input to the multiplexing processing unit 22.

The multiplexing processing unit 22 successively generates frame data of one signal system arranged in time sequence so as to multiplex the broadcast wave data of AM, FM, DTV respectively demodulated by the demodulation circuits 21. The pieces of frame data generated by the multiplexing processing unit 22 are successively transmitted to the head unit 40 by the transmission processing unit 32 that is provided in the data transmission device 30.

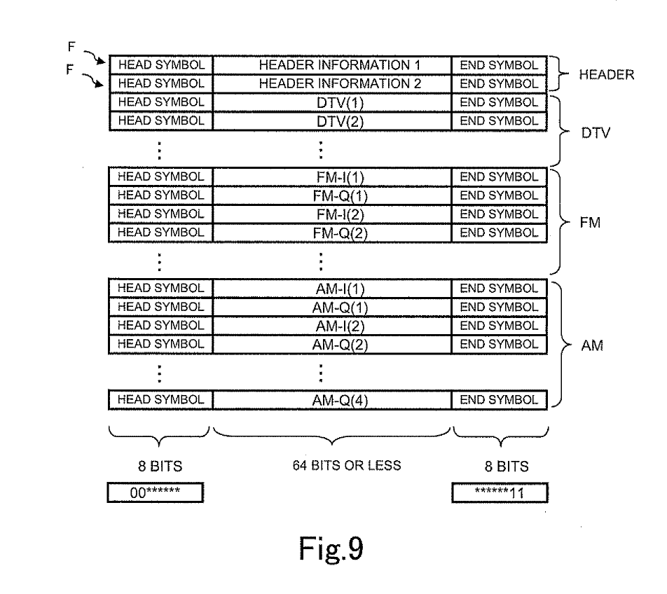

FIG. 9 illustrates an example of a transmission frame generated by the multiplexing processing unit 22. Each transmission frame F includes an 8-bit head symbol region for storing header information, a data region for storing variable length data of up to 64 bits, and an 8-bit end symbol region for storing end information of each frame. In one multiplexing processing, up to 256 frames are generated.

The first frame and the second frame store header information 1, 2 on the entire transmission frames. The third to 256-th frames store broadcast wave data of AM, FM, DTV each of which is actually received and demodulated to a predetermined stage.

The first two bits of the head symbol region store “00” representing the head of the frame. Subsequent six bits store data representing a data length of each frame. The last two bits of the end symbol region store “11” representing the end of the frame. The header information on the entire transmission frames includes data such as channel select station information of each signal system, the number of pieces of data, the number of frames, and the like. It should be noted that the frame configuration is merely an example. The frame configuration applied to the antenna device of the present invention is not limited to such an example.

As shown in FIG. 8, the head unit 40 includes a data transmission device 60 having a reception processing unit 63 and a transmission processing unit 62, an output processing unit 50 constituted by a digital signal processor and a peripheral circuit thereof, a control unit 54, and the like. The output processing unit 50 includes a signal separation processing unit 51, reproduction units 52 (52a, 52b, 52c), and D/A converters 53 (53a, 53b, 53c).

Further, the head unit 40 is provided with a clock circuit 55 including a clock signal source and a frequency divider for generating a clock signal of a required frequency. The signal separation processing unit 51, the reproduction units 52, the D/A converters 53, the control unit 54, the data transmission device 60, and the like are configured to operate on the basis of the clock signal generated by the clock circuit 55.

Full-duplex communication is performed via the data transmission lines L (L1, L2) between the data transmission device 30 provided in the antenna device 14 and the data transmission device 60 provided in the head unit 40. In the present embodiment, the hardware configuration, the communication protocol, and the like for achieving the full-duplex communication are not particularly limited, and are realized appropriately using a well-known hardware configuration and a well-known known communication protocol.

The frame data which is transmitted from the transmission processing unit 32 of the antenna device 14 and is received by the reception processing unit 63 of the head unit 40 is input to the signal separation processing unit 51. The frame data is separated into pieces of original broadcast wave data by the signal separation processing unit 51, and the pieces of separated broadcast wave data are input to the reproduction units 52. The demodulated digital signals reproduced by the reproduction units 52 are converted into analog signals by the D/A converters 53, and the analog signals are output to respective audio apparatuses.

When an operator operates the controller 60 (see FIG. 7A) of the audio apparatus, a desired broadcast wave and a desired broadcast station are selected. When control information such as channel select information is input from the controller 60 to the control unit 54 of the head unit 40, the control unit 54 generates frame data including control information such as the channel select information, and the frame data is transmitted by the transmission processing unit 62 to the reception processing unit 33 of the antenna device 14.

A frame generated by the control unit 54 includes an 8-bit head symbol region, a 16-bit fixed-length data region, and an 8-bit end symbol region for storing end information of each frame. The data structures of the head symbol region and the end symbol region are the same as those explained above with reference to FIG. 9, and control information such as channel select information is set in the data region.

The control information such as channel select information included in the frame data transmitted by the transmission processing unit 62 of the head unit 40 to the reception processing unit 33 of the antenna device 14 is input to the high frequency control unit 15. The high frequency control unit 15 is configured to control the antenna amplifier devices 1 and the demodulation processing unit 20 on the basis of the control information.

The antenna amplifier device 1 will be hereinafter explained in detail.

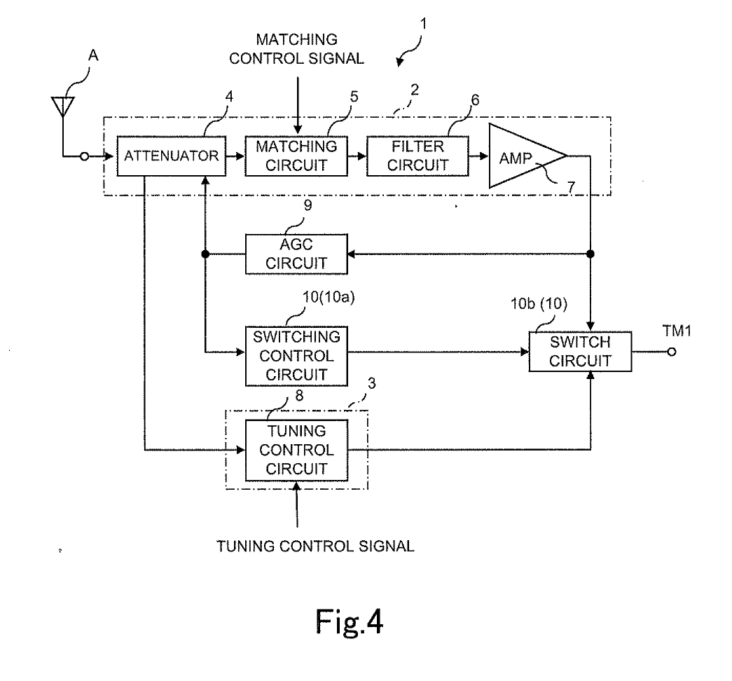

As shown in FIG. 4, each of the antenna amplifier devices 1 is arranged near to the antenna A, and includes a weak input circuit 2 and a strong input circuit 3 into which the high frequency signals received by the antennas A are input, and a switching circuit 10 for selectively outputting one of the outputs from the weak input circuit 2 and the strong input circuit 3 to the demodulation processing unit 20 (see FIG. 8) at a later stage.

The switching circuit 10 includes an analog switch circuit 10b and an analog switching control circuit 10a. The switch circuit 10b receives both of the output signal from the weak input circuit 2 and the high frequency output signal from the strong input circuit 3, and outputs any one of the high frequency signals to a later stage. The switching control circuit 10a controls the switch circuit 10b on the basis of an AGC signal output from an AGC circuit 9.

When the automobile travels in a low magnetic field area, a high frequency signal received by the antenna A is processed by the weak input circuit 2, and is thereafter input to the demodulation processing unit 20 (see FIG. 8) via the switching circuit 10. When the automobile travels in a high magnetic field area, a high frequency signal received by the antenna A is processed by the strong input circuit 3, and is thereafter input to the demodulation processing unit 20 (see FIG. 8) via the switching circuit 10.

The weak input circuit 2 includes an attenuator 4, a matching circuit 5, a filter circuit 6, and an amplification circuit 7 having a constant amplification factor. In addition, the AGC circuit 9 is provided to control the attenuator 4 to control an attenuation factor of a high frequency signal in accordance with the output signal level of the amplification circuit 7.

The high frequency signal attenuated to an appropriate level by the attenuator 4 adjusted to a predetermined attenuation factor on the basis of the output signal of the AGC circuit 9 is passed through the matching circuit 5 and the filter circuit 6, and is amplified by the amplification circuit 7 without any waveform distortion. It should be noted that the filter circuit 6 does not configure an indispensable circuit block, but may be provided as necessary.

The matching circuit 5 incorporated into the antenna amplifier device 1 corresponding to the FM broadcasting wave or the digital television DTV broadcast wave is constituted using a well-known LC resonance circuit, for example. The frequency characteristics of the matching circuit 5 are adjusted on the basis of a matching control signal output from the high frequency control unit 15 in accordance with the channel select information explained with reference to FIG. 8. The matching circuit 5 matches the impedance with that of the antenna A.

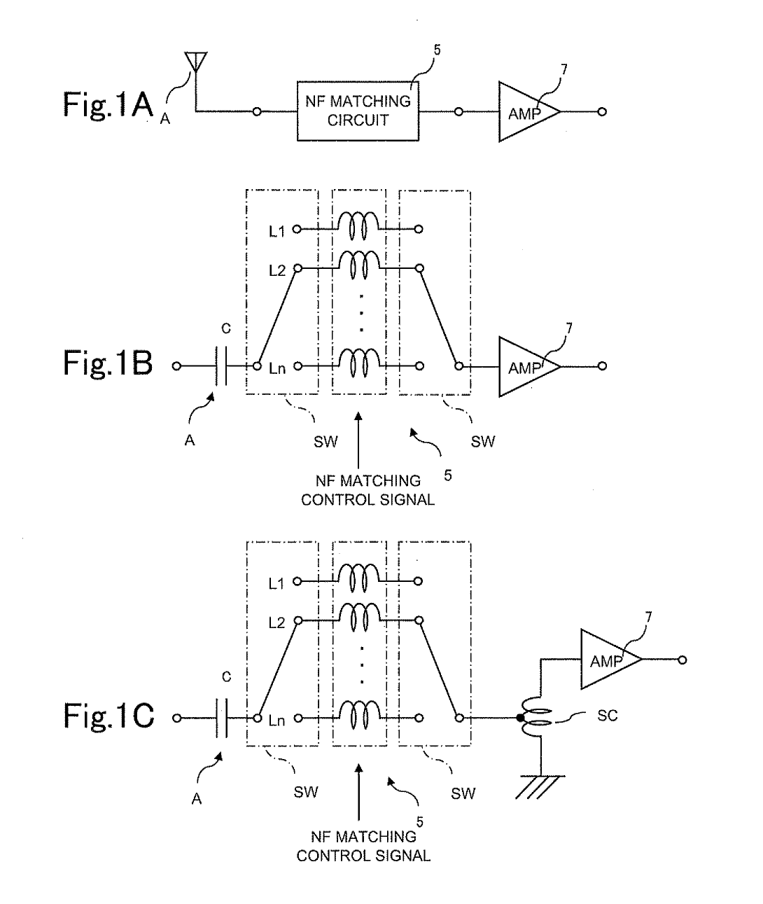

As shown in FIG. 1A, the matching circuit 5 incorporated into the antenna amplifier device 1 for receiving a broadcast wave having a wavelength of 10 m or more (broadcast wave of HF (high frequency), MF (medium frequency), or the like) such as an AM broadcasting wave is constituted by an NF matching circuit for switching the input impedance to the amplification circuit 7 in accordance with the reception frequency.

The antenna A for receiving the broadcast wave having a wavelength of 10 m or more such as an AM broadcasting wave has an extremely short length relative to the wavelength thereof, and the input impedance thereof is capacitive and has an extremely high value. An FET having a high input impedance is preferably used as the amplification circuit 7 corresponding to the broadcast wave.

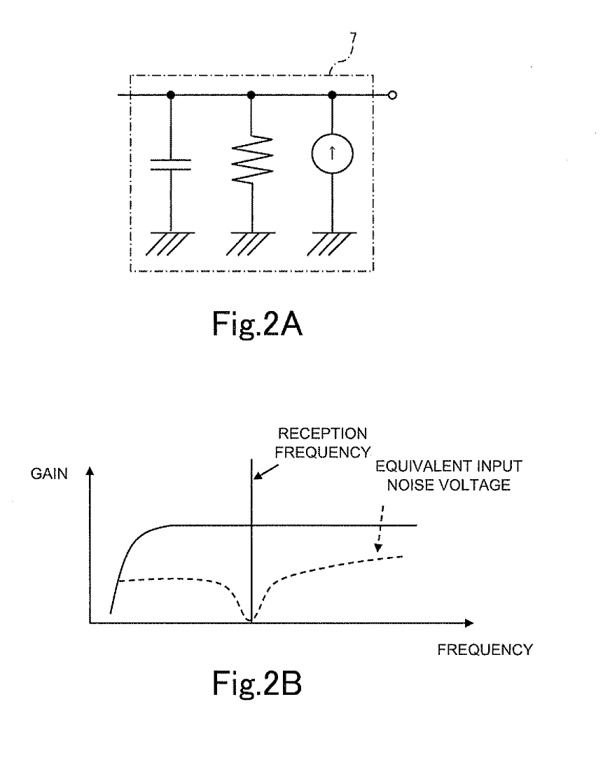

FIG. 2A illustrates an input equivalent circuit of the FET. The input impedance thereof is several kilo ohms. Accordingly, when the impedance of the signal source including the antenna increases, an equivalent input noise current, i.e., a noise source of the FET element itself, increases, which generates a so-called shot noise. Therefore, particularly in a case where an input is weak, the amplification circuit 7 improves the signal level, but at the same time, the equivalent input noise voltage increases, which reduces the S/N ratio.

Accordingly, the NF matching circuit 5 is provided as shown in FIG. 1B. The NF matching circuit 5 includes a plurality of coils L1, L2, . . . , Ln (n is an arbitrary integer of 2 or more) having different inductances and switches SW for connecting one of the coils selected according to the reception frequency, between the antenna A and the amplification circuit 7. For the AM broadcasting wave of 531 kHz to 1602 kHz, the value “n” is set from 5 to 6, and the NF matching is made so as to achieve the switching in five to six steps in this frequency band.

The LC resonance circuit is constituted by the NF matching circuit 5 that is connected in series with the antenna (of a capacitance C) having a capacitive impedance. The switch SW is switched so as to reduce the input impedance to the amplification circuit 7 on the basis of a NF matching control signal output from the high frequency control unit 15 in accordance with the reception frequency, i.e., the channel select information explained with reference to FIG. 8.

In FIG. 1B, the switches SW are provided at both ends of the coils L1 to Ln. Alternatively, as far as the circuit is not affected by an unselected coil, all ends of the coils closer to the antenna may be connected to the antenna, and the switch SW may be provided only on the other ends. Still alternatively, only the ends closer to the antenna may be connected to the switch SW, and all the other ends may be connected to the amplifier 7.

A mechanical relay circuit can be employed as the switch SW incorporated into the circuit. Furthermore, a semiconductor switch such as an RF-MEMS switch can be employed.

FIG. 2B is a diagram illustrating characteristics of the equivalent input noise voltage with respect to the reception frequency. Using the switches SW to be switched in accordance with the reception frequency, the NF matching circuit 5 is configured to reduce the equivalent input noise voltage by changing the resonance frequency of the resonance circuit.

FIG. 1C illustrates an example where a step-up coil SC is interposed between the NF matching circuit 5 and the amplification circuit 7. The step-up coil SC is a transformer having a larger turn ratio of a secondary coil with respect to a primary coil so that the secondary impedance is further increased.

When the step-up coil SC is used, a high frequency signal is supplied to the amplification circuit 7 via the step-up coil SC while the NF matching circuit 5 maintains the NF matching. Therefore, this circuit configuration is advantageous in that a signal voltage having a high S/N ratio can be obtained while the shot noise of the FET is effectively reduced.

The above NF matching circuit 5 is the example including the plurality of coils and the switches using the capacitive antenna impedance. Alternatively, the NF matching circuit 5 may be constituted by a resonance circuit constituted by a combination of capacitors and coils.

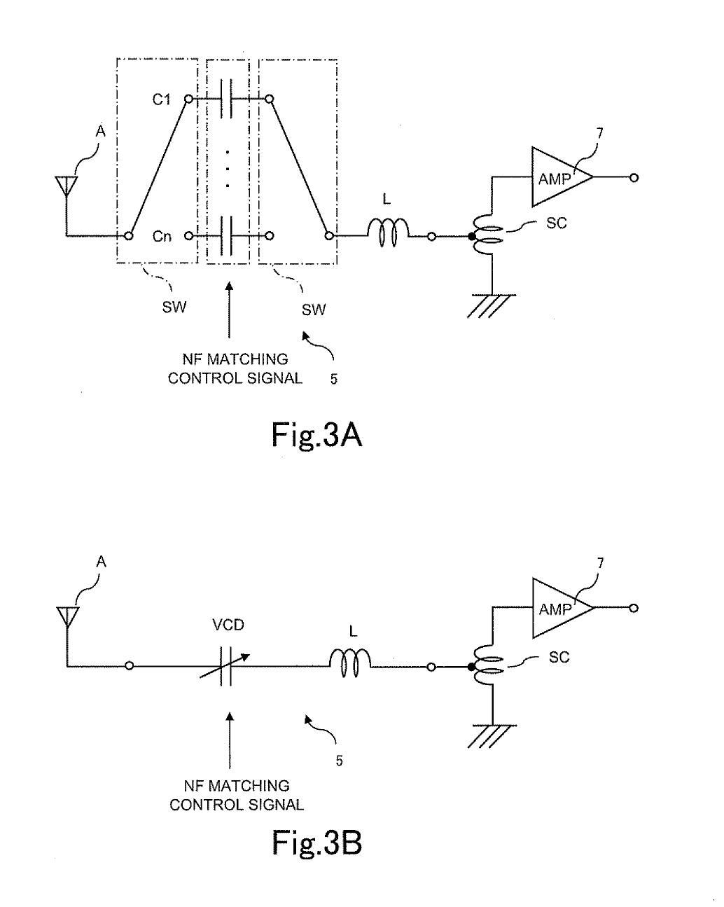

FIG. 3A shows the NF matching circuit 5 constituted by a series resonance circuit having coils and capacitors, wherein the series resonance circuit includes a plurality of capacitors C1 to Cn (n is an arbitrary integer of 2 or more) having different capacitances and the switches SW for connecting on of the capacitors C, selected according to the reception frequency, to the coil L.

Also in this case, using the switches SW switched in accordance with the reception frequency, the NF matching circuit 5 is configured to reduce the equivalent input noise voltage by changing the resonance frequency of the resonance circuit.

FIG. 3B shows the NF matching circuit 5 constituted by a series resonance circuit having coils and capacitors, wherein the capacitor is constituted by a variable capacitance diode VCD of which capacitance is variably adjusted in accordance with the reception frequency. In this case, using a control voltage applied to the variable capacitance diode VCD in accordance with the reception frequency, the NF matching circuit 5 is configured to reduce the equivalent input noise voltage by changing the resonance frequency of the resonance circuit.

The above strong input circuit 3 has a tuning circuit 8 for removing a strong input interfering wave from the high frequency signal input via the attenuator 4.

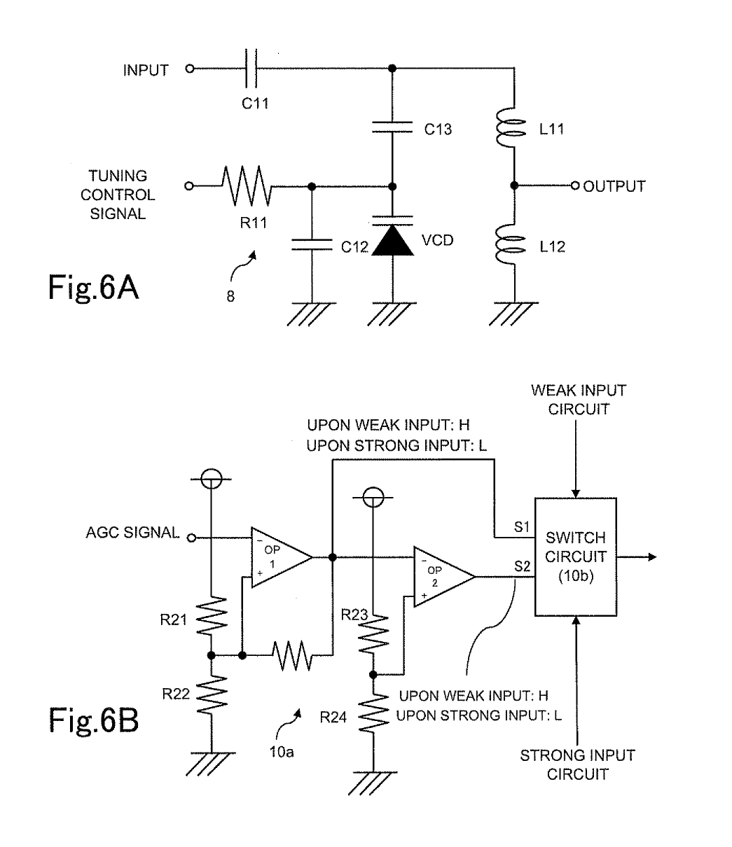

FIG. 6A illustrates an example of the tuning circuit 8. The tuning circuit 8 is constituted by an LC resonance circuit including coils L11, L12, capacitors C11, C12, C13, and the variable capacitance diode VCD. This circuit is suitable for adjusting the capacitance of the variable capacitance diode VCD on the basis of a tuning control signal input via a resistor R11, attenuating frequency components other than a selected frequency, and outputting an AM broadcasting wave and an FM broadcasting wave to a later stage.

The tuning control signal is output from the high frequency control unit 15 on the basis of the channel select information explained with reference to FIG. 8. The above tuning circuit 8 is only an example, and the circuit configuration is not limited thereto.

In other words, the high frequency signal that is input to the strong input circuit 3 via the attenuator 4 is tuned to a frequency band of a desired wave by the tuning circuit 8, so that an interfering wave is removed.

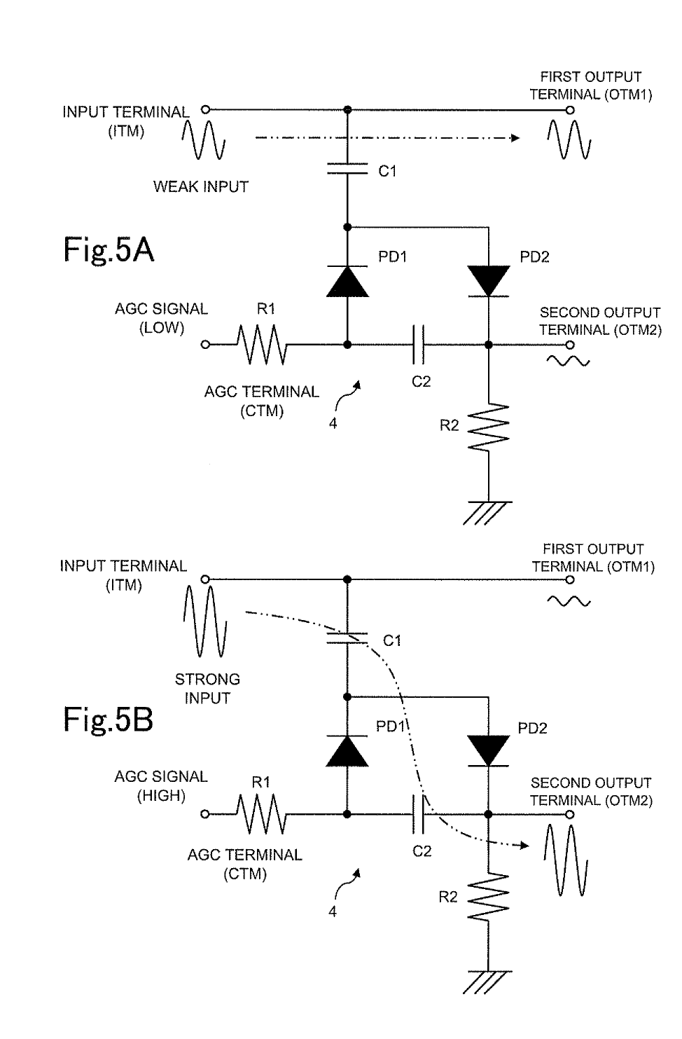

As shown in FIGS. 5A, 5B, the attenuator 4 includes the capacitors C1, C2, PIN diodes PD1, PD2, and resistors R1, R2.

The resistor values of the PIN diodes PD1, PD2 are controlled based on the AGC signal that is input from an AGC terminal CTM. The high frequency signal that is input from an input terminal ITM is attenuated with a predetermined attenuation factor. The attenuated signal is output from a first output terminal OTM1 to a variable matching circuit 5 at a later stage.

The resistor R2 is connected between the cathode of the PIN diode PD2 and the ground. A second output terminal OTM2 is provided at a connection point between the PIN diode PD2 and the resistor R2.

The AGC circuit 9 is a feedback circuit including a diode detector circuit for detecting an output level of the amplification circuit 7 and an operational amplifier for amplifying an output of the diode detector circuit. As the output level of the amplification circuit 7 increases, the signal level of the AGC signal, i.e., increases. As the output level of the amplification circuit 7 decreases, the signal level of the AGC signal decreases.

In other words, when the electric field strength of the high frequency signal received by the antenna A attains an extremely high level, i.e., a strong input state, there is a potential risk that waveform distortion may occur in the amplification circuit 7. Therefore, the signal level of the AGC signal increases in order to increase the attenuation factor of the signal using the attenuator 4. On the contrary, when the electric field strength of the high frequency signal received by the antenna A attains a low level, i.e., a weak input state, waveform distortion will not occur in the amplification circuit 7. Therefore, the signal level of the AGC signal decreases in order to decrease the attenuation factor of the signal using the attenuator 4.

As shown in FIG. 5A, when an input is weak, the signal level of the AGC signal that is input from the AGC terminal CTM attains a sufficiently low level, the PIN diodes PD1, PD2 are substantially in an open state. Accordingly, the high frequency signal input via the input terminal ITM is output from the first output terminal OTM1 without any attenuation, and the high frequency signal greatly attenuated is output from the second output terminal OTM2.

As shown in FIG. 5B, when an input is strong, the signal level of the AGC signal that is input from the AGC terminal CTM attains a sufficiently high level, the PIN diodes PD1, PD2 biased in a forward direction are brought into substantially a shorted state. Accordingly, the high frequency signal input via the input terminal ITM is attenuated by the PIN diodes PD1, PD2 and the resistor R2 and is output from the first output terminal OTM1, and the high frequency signal not being attenuated is output from the second output terminal OTM2. The degree of attenuation of the high frequency signal by the attenuator 4 is adjusted on the basis of the signal level of the AGC signal.

In other words, the attenuator 4 includes an attenuation circuit, the first output terminal OTM1, and the second output terminal OTM2. The attenuation circuit includes the PIN diodes PD1, PD2 controlled by the AGC signal. When an input is strong, the first output terminal OTM1 outputs to the amplification circuit 7 the high frequency signal attenuated by the attenuation circuit with a large attenuation factor, and when an input is weak, the first output terminal OTM1 outputs to the amplification circuit 7 the high frequency signal attenuated by the attenuation circuit with a small attenuation factor. When an input is weak, the second output terminal OTM2 outputs to the tuning circuit 8 the high frequency signal attenuated with a small attenuation factor, and when an input is weak, the second output terminal OTM2 outputs to the tuning circuit 8 the high frequency signal attenuated with a large attenuation factor.

FIG. 6B illustrates an example of the switching circuit 10. The analog switch circuit 10b receives the output signal from the weak input circuit 2 and the output signal from the strong input circuit 3. One of the output signal from the weak input circuit 2 and the output signal from the strong input circuit 3 is output to a later stage on the basis of the signal values input to control signal terminals S1, S2 of the switch circuit 10b.

When the control signal terminal S1 is on a high level and the control signal terminal S2 is on a low level, the output signal from the weak input circuit 2 is output to the later stage. When the control signal terminal S1 is on a low level and the control signal terminal S2 is on a high level, the output signal from the strong input circuit 3 is output to the later stage.

The switching control circuit 10a includes a first operational amplifier OP1 and a second operational amplifier OP2. A first reference voltage is obtained by dividing a power supply voltage with a voltage divider circuit including resistors R21, R22. The first reference voltage is input to a non-inverted input terminal of the first operational amplifier OP1. The AGC signal is input to an inverted input terminal thereof.

When the AGC signal is higher than the first reference voltage, the first operational amplifier OP1 outputs a low level. When the AGC signal is lower than the first reference voltage, the first operational amplifier OP1 outputs a high level.

The first reference voltage is set to a value much lower than the signal voltage of the AGC signal corresponding to the maximum attenuation factor of the attenuator 4 with which the signal can be attenuated without causing waveform distortion in the high frequency signal amplified by the amplification circuit 7.

The second operational amplifier OP2 is a circuit for inverting the output logic of the first operational amplifier OP1. A second reference voltage is obtained by dividing the power supply voltage with a voltage divider circuit including resistors R23, R24. The second reference voltage is input to a non-inverted input terminal of the second operational amplifier OP2. The output of the first operational amplifier OP1 is input to an inverted input terminal thereof. The second reference voltage is set to a value half of the power supply voltage.

In the above example, the antenna device 14 includes the antenna amplifier devices 1 for amplifying the high frequency signals received by the antennas of different signal systems, i.e., AM, FM, DTV, the demodulation processing unit 20, and the data transmission device 30. However, the received broadcast waves are not limited to AM, FM, DTV. Further, the number of connected antennas is not to be considered limited to three.

The antenna device 14 according to the present invention may include at least one antenna amplifier device 1 for receiving a broadcast wave having a wavelength of 10 m or more such as the AM broadcasting wave described above.

The configuration of the demodulation processing unit 20 is not limited to the above example. The high frequency signal received by the antenna may not necessarily be transmitted to the head unit after it is completely demodulated by the demodulation processing unit 20. Alternatively, after the high frequency signal received by the antenna is demodulated to an intermediate stage by the demodulation processing unit 20, the high frequency signal may be transmitted to the head unit, and the head unit may have a block for executing the final demodulation processing. In any case, the specific circuit configuration of the demodulation processing unit 20 may be appropriately changed in accordance with the type of the received broadcast wave.

In the example of the above embodiment, the antenna amplifier device 1 is incorporated into the antenna device 14. However, the antenna amplifier device 1 according to the present invention may not be incorporated into the antenna device 14, and may used as a stand-alone configuration as an optional extra. In this case, the switch SW may be switched in accordance with the reception frequency from a tuner device, or an NF matching control signal for controlling the variable capacitance diode VCD may be output to the antenna amplifier device 1.

The above embodiment is merely an example of the present invention. It is to be understood that a specific configuration and the like of each block can be appropriately changed in its design as long as the functions and effects of the present invention can be achieved.

What is claimed is:

1. An antenna amplifier device installed near to an antenna provided in a mobile object, the antenna amplifier device comprising:
an amplification circuit for amplifying a high frequency signal received by the antenna; and
an NF matching circuit provided between the amplification circuit and the antenna of which input impedance is capacitive, the NF matching circuit switching the input impedance to the amplification circuit in accordance with a reception frequency.

2. The antenna amplifier device according to claim 1, wherein
the NF matching circuit includes a plurality of coils having different inductances, and at least one switch for connecting one of the coils, selected in accordance with the reception frequency, between the antenna and the amplification circuit.

3. The antenna amplifier device according to claim 1, wherein
the NF matching circuit is constituted by a series resonance circuit including coils and capacitors, and the series resonance circuit includes a plurality of capacitors having different capacitances, and at least one switch for connecting one of the capacitors, selected in accordance with the reception frequency, to the coil.

4. The antenna amplifier device according to claim 1, wherein
the NF matching circuit is constituted by a series resonance circuit including a coil and a capacitor, and the capacitor includes a variable capacitance diode of which capacitance is variably adjusted in accordance with the reception frequency.

5. The antenna amplifier device according to claim 1, wherein
the high frequency signal received by the antenna is a broadcast wave having a wavelength of 10 m or more.

6. An antenna amplifier device installed near to an antenna provided in a mobile object, the antenna amplifier device comprising:
an amplification circuit for amplifying a high frequency signal received by the antenna;
an NF matching circuit provided between the amplification circuit and the antenna of which input impedance is capacitive, the NF matching circuit switching the input impedance to the amplification circuit in accordance with a reception frequency; and
a step-up coil interposed between the NF matching circuit and the amplification circuit.

7. The antenna amplifier device according to claim 6, wherein
the NF matching circuit includes a plurality of coils having different inductances, and at least one switch for connecting one of the coils, selected in accordance with the reception frequency, between the antenna and the amplification circuit.

8. The antenna amplifier device according to claim 6, wherein
the NF matching circuit is constituted by a series resonance circuit including coils and capacitors, and the series resonance circuit includes a plurality of capacitors having different capacitances, and at least one switch for connecting one of the capacitors, selected in accordance with the reception frequency, to the coil.

9. The antenna amplifier device according to claim 6, wherein
the NF matching circuit is constituted by a series resonance circuit including a coil and a capacitor, and the capacitor includes a variable capacitance diode of which capacitance is variably adjusted in accordance with the reception frequency.

10. The antenna amplifier device according to claim 6, wherein
the high frequency signal received by the antenna is a broadcast wave having a wavelength of 10 m or more.

11. An antenna device provided in a mobile object, the antenna device comprising:
a plurality of antenna amplifier devices in each including an amplification circuit for amplifying a high frequency signal received by the antenna, and an NF matching circuit provided between the amplification circuit and the antenna of which input impedance has a capacitance, the NF matching circuit for switching the input impedance to the amplification circuit in accordance with a reception frequency;
a plurality of demodulation units in each for demodulating the high frequency signal output from each of the antenna amplifier devices;
a multiplexing processing unit for multiplexing the demodulated signal demodulated by each of the demodulation units into a signal string of one system;
a data transmission device for transmitting the demodulated signal constituted by the signal string of one system multiplexed by the multiplexing processing unit to a head unit via a data transmission line; and
a high frequency control unit for controlling each of the NF matching circuits based on channel select information transmitted from the head unit via the data transmission device.
